(19) United States
(12) Patent Application Publication
(10) Pub. No.: US 2015/0357990 A1
(43) Pub. Date: Dec. 10, 2015

(54) MOBILE TERMINAL

(71) Applicant: LG ELECTRONICS INC., Yongdungpo-gu, Seoul (KR)

(72) Inventors: Sungkwon JANG, Seoul (KR); Jeonghwan HWANG, Seoul (KR); Inkuk YEO, Seoul (KR)

(21) Appl. No.: 14/399,736

(22) PCT Filed: Jul. 8, 2013
(86) PCT No.: PCT/KR2013/006063

§ 371 Date: Nov. 7, 2014

(51) Int. Cl. H03H 7/40; H03J 1/06

(52) U.S. Cl. CPC H03H 7/40; H03J 1/06

(57) ABSTRACT

A mobile terminal according to the present invention can compensate for impedance mismatch of a tuner due to a user's grip, thereby improving communication quality.

### TECHNICAL FIELD

The present invention is related to a mobile terminal and more particularly, a mobile terminal capable of preventing degradation of radio sensitivity due to a user's grip on the mobile terminal.

### BACKGROUND ART

As functions of a terminal such as a personal computer, notebook, mobile phone, and smart phone are diversified, the terminal is now implemented in the form of a multimedia player equipped with multi-functions for capturing pictures or video, playing music or video files, game, and receiving broadcasting programs.

To support and enhance the increasing number of functions in a terminal, improving structural part and/or software part of the terminal is now being considered. As various types of terminals today, including mobile terminals, provide various complex functions, a menu structure is accordingly getting more complicated.

In most cases, users perform communication while gripping their mobile terminal. Therefore, sensitivity of communication may be degraded due to a hand effect. In this regard, demand from users for a means to prevent degradation of sensitivity of communication due to the users' grip on their mobile terminal is growing rapidly along with research on the means.

### DISCLOSURE OF INVENTION

### Technical Problem

An object of the present invention is to provide a mobile terminal capable of preventing degradation of radio sensitivity due to a user's grip on the mobile terminal.

Technical objects of the present invention are not limited to those objects described above; other technical objects not mentioned above can be clearly understood from what are described below by those skilled in the art to which the present invention belongs.

### Solution to Problem

To achieve the technical object, a mobile terminal according to one embodiment of the present invention comprises a mobile communication module including a tuner matching a predetermined target resonance frequency for mobile communication; an information acquisition unit obtaining information related to impedance mismatch of the tuner, which is caused by a user's grip on the mobile terminal and changes resonance frequency of the tuner; a controller generating an impedance control signal for compensating for the resonance frequency of the tuner from the changed resonance frequency to the target resonance frequency based on the information related to impedance mismatch of the tuner; and a frequency compensation unit changing the impedance of the tuner mismatched by the user's grip on the mobile terminal so that the impedance of the tuner can match the target resonance frequency in response to the impedance control signal.

The information acquisition unit includes a touch position sensing module disposed on a side surface of the mobile terminal body, and the information related to impedance mismatch of the tuner can include position information of a plurality of touch inputs due to the user's grip on the mobile terminal, which is sensed by the touch position sensing module.

The mobile terminal further comprises a memory storing information related to impedance mismatch of the tuner according to a grip type of the user. If the grip type of the user is sensed by the touch position sensing module, the controller searches the memory to generate an impedance control signal due to the sensed grip type.

The frequency compensation unit controls capacitance of the tuner in response to the impedance control signal so that the impedance of the tuner can be changed to match the target resonance frequency. The frequency compensation unit comprises a plurality of capacitors; and a plurality of switches connecting one of the plurality of capacitors to the tuner in response to the impedance control signal.

To achieve the technical object, a mobile communication module according to another embodiment of the present invention comprises a tuner matching a predetermined target resonance frequency for mobile communication; an information acquisition unit obtaining information related impedance mismatch of the tuner, which is caused by a user's grip on the mobile terminal and induces change of resonance frequency of the tuner; a communication controller generating an impedance control signal for compensating for a difference between resonance frequency of the tuner and the target resonance frequency based on the information related to impedance mismatch of the tuner; and a frequency compensation unit changing the impedance of the turner to match the target resonance frequency in response to the impedance control signal.

The information related to impedance mismatch of the tuner includes information of impedance change of the tuner caused by the user's grip on the mobile terminal. The information of impedance mismatch of the tuner can include information of resonance frequency change of the turner caused by the user's grip on the mobile terminal. The information related to impedance mismatch of the tuner can include position information of a plurality of touch inputs due to the user's grip sensed by a touch input sensing module installed on a side surface of the mobile terminal body.

The mobile communication module is linked to a memory storing information related to impedance mismatch of the tuner according to a grip type of the user. The communication controller searches the memory if a grip type of the user is received from the touch position sensing module and generates an impedance control signal according to the sensed grip type.

The frequency compensation unit can change the impedance of the tuner to match the target resonance frequency of the tuner by controlling capacitance of the tuner in response to the impedance control signal.

### Advantageous Effects of Invention

A mobile terminal according to the present invention can prevent degradation of communication quality due to a user's grip on the mobile terminal.

### BRIEF DESCRIPTION OF DRAWINGS

The accompanying drawings, which are included to provide a further understanding of the present invention and constitute a part of specifications of the present invention, illustrate embodiments of the present invention and together with the corresponding descriptions serve to explain the principles of the present invention.

FIG. 1 is a block diagram of a mobile terminal according to an embodiment of the present invention;

FIG. 2 is a block diagram of a mobile terminal according to another embodiment of the present invention;

FIG. 3 illustrates a resonance frequency compensation operation of a tuner carried out in a mobile terminal according to the present invention;

FIG. 4 illustrates one example of a method for operating a mobile terminal according to the present invention;

FIG. 5 illustrates another example of a method for operating a mobile terminal according to the present invention;

FIG. 6 illustrates an example where resonance frequency compensation for a tuner is carried out according to a method for operating a mobile terminal of FIG. 5;

FIG. 7 is a graph illustrating a method for compensating for resonance frequency of a tuner of a mobile terminal according to a method for operating a mobile terminal of FIG. 6;

FIG. 8 is a flow diagram illustrating a yet another example of a method for operating a mobile terminal according to the present invention;

FIG. 9 is a block diagram of a mobile communication module of a mobile terminal according to the present invention, intended for carrying out a method for operating a mobile terminal of FIG. 8; and

FIG. 10 illustrates examples where a sensing module for sensing a touch position due to a user's grip on a mobile terminal is disposed therein according to the present invention.

### BEST MODE FOR CARRYING OUT THE INVENTION

The technical object, characteristics, and advantages of the present invention will now be more clearly understood from detailed descriptions given below. In what follows, preferred embodiments according to the present invention will be given with reference to appended drawings. Throughout the document, the same reference number represents the same component. In the following description, if it is decided that the detailed description of known function or configuration related to the invention obscures the technical principles of the present invention, the corresponding description is omitted.

In what follows, a mobile terminal according to the present invention will be described in more detail with reference to appended drawings. A suffix such as “module” and “unit” may be assigned or used interchangeably to refer to elements or components. Use of such a suffix herein is merely intended to facilitate description of the specification, and the suffix itself is not intended to give any special meaning or function.

The mobile terminal in this document may include a cellular phone, a smart phone, a notebook computer, a digital broadcasting terminal, personal digital assistants (PDA), a portable multimedia player (PMP), and a navigation terminal; however, the technical scope of the present invention is not limited to the terminals above.

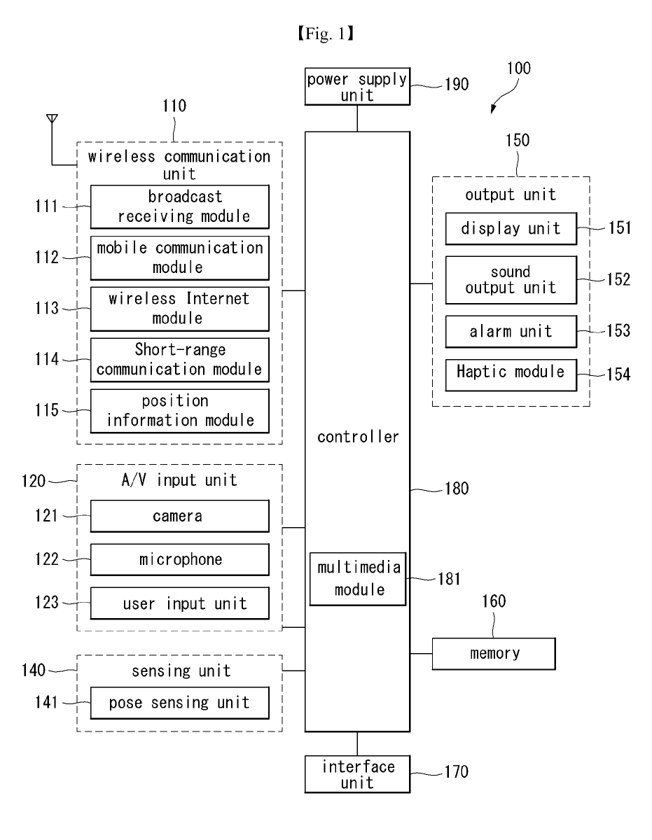

FIG. 1 is a block diagram of a mobile terminal according to an embodiment of the present invention. With reference to FIG. 1, the mobile terminal 100 comprises a wireless communication unit 110, an Audio/Video (A/V) input unit 120, a user input unit 130, a sensing unit 140, an output unit 150, a memory 160, an interface unit 170, a controller 180, and a power supply unit 190. Although FIG. 1 shows a mobile terminal having various components, it should be understood that implementing all of the illustrated components is not a mandatory requirement; a mobile terminal 100 can be equipped with a larger or smaller number of components than what are shown in FIG. 1.

In what follows, the constituting elements are described one after another.

The wireless communication unit 110 includes one or more components that permit wireless communication between the mobile terminal 100 and a wireless communication system or a network in which the mobile terminal 100 is located. For example, the wireless communication unit 110 includes a broadcast receiving module 111, a mobile communication module 112, a wireless Internet module 113, a short-range communication module 114 and a position information module 115.

The broadcast receiving module 111 receives a broadcast signal and/or broadcast-related information from an external broadcast managing server via a broadcast channel.

The broadcast channel may include a satellite channel or a terrestrial channel or both. The broadcast managing server may refer to a server that generates and transmits broadcast signals and/or broadcast-related information or a server receiving previously generated broadcast signals and/or broadcast-related information and transmitting the broadcast signals and/or the broadcast-related information to the mobile terminal 100. The broadcast signal may include not only a TV broadcast signal, radio broadcast signal, and data broadcast signal, but also a broadcast signal in the form of a TV broadcast signal or a radio broadcast signal combined with a data broadcast signal.

The broadcast-related information may refer to the information about a broadcast channel, a broadcast program, or a broadcast service provider. The broadcast-related information may even be provided over a mobile communication network. In the latter case, the broadcast-related information may be received via the mobile communication module 112.

The broadcast-related information can be realized in various ways. Examples of broadcast-related information include an electronic program guide (EPG) of digital multimedia broadcasting (DMB) and an electronic service guide (ESG) of digital video broadcast-handheld (DVB-H).

The broadcast receiving module 111 receives broadcast signals through various types of broadcast systems. As a non-limiting example, the broadcast systems include digital multimedia broadcasting-terrestrial (DMB-T), digital multimedia broadcasting-satellite (DMB-S), media forward link only (MediaFLO), digital video broadcast-handheld (DVB-H), and integrated services digital broadcast-terrestrial (ISDB-T). The broadcast receiving module 111 may also receive multicast signals. The broadcast receiving module 111 can be configured to be suitable not only for the digital broadcast system described above but also for other types of broadcast systems providing broadcast signals.

The broadcast signals and/or the broadcast-related information received by the broadcast receiving module 111 may be stored in the memory 160.

The mobile communication module 112 transmits and receives radio signals to and from at least one of a base station, an external terminal or a server over a mobile communication network. The radio signals may include voice call signals, video telephony call signals or data in various forms according to the transmission and reception of text and/or multimedia messages.

The wireless Internet module 113 refers to a module intended for wireless Internet access. This wireless Internet module 113 may be internally or externally coupled to the mobile terminal 100. Suitable technologies for wireless Internet include, but are not limited to, WLAN (Wireless LAN), Wi-Fi, Wireless broadband (Wibro), World Interoperability for Microwave Access (Wimax), High Speed Downlink Packet Access (HSDPA), and Long Term Evolution (LTE).

The short-range communication module 114 facilitates relatively short-range communications. Suitable technologies for short-range communication include, but are not limited to, radio frequency identification (RFID), infrared data association (IrDA), ultra-wideband (UWB), and ZigBee.

The position information module 115 identifies or obtains a location of the mobile terminal 100. The position information module 115 obtains position information by using a global navigation satellite system (GNSS). The GNSS is a term used to describe radio navigation satellite systems which orbit the Earth and transmit reference signals with which radio navigation receivers of predetermined types on the surface or near the surface of the Earth can determine their positions. The GNSS includes a global position system (GPS) operated by the U.S.A.; Galileo, operated by Europe; a global orbiting navigational satellite system (GLONASS) operated by Russia; COMPASS, operated by China; and a quasi-zenith satellite system (QZSS) operated by Japan.

As a typical example of the GNSS, the position information module 115 is a GPS module. The position information module 115 calculates three-dimensional position information of one location (object) at a particular time point in terms of latitude, longitude, and altitude by using information about distances of the location (object) from at least three satellites and information about the time at which the distances are measured and applying trigonometry to the obtained distance information. In a different implementation, while three satellites are used to calculate position and time information, an auxiliary satellite signal is employed additionally to correct the error in the calculated position and time information. The GPS module continuously calculates a current position in real time and calculates velocity information based on the position information.

With reference to FIG. 1, the audio/video (A/V) input unit 120 is intended to receive an audio or video signal and includes a camera 121 and a microphone 122. The camera 121 processes image frames of still pictures or video obtained by an image sensor in a photographing mode or a video telephony mode. The processed image frames are displayed on a display unit 151.

The image frames processed by the camera 121 may be stored in the memory 160 or transmitted to an external device through the wireless communication unit 110. Two or more cameras 121 can be installed depending on the composition type of the mobile terminal 100.

The microphone 122 receives an external audio signal through a microphone while the mobile terminal 100 is in a phone call mode, a recording mode, or a voice recognition mode. The received audio signal is processed and converted into digital voice data. In the call mode, the processed voice data is transformed into a format suitable for transmission to a mobile communication base station via the mobile communication module 112. Various noise removing algorithms to remove noise generated in the course of receiving the external audio signal can be applied to the microphone.

The user input unit 130 generates input data for the user to control operation of the mobile terminal 100. The user input unit 130 can be composed of a keypad, a dome switch, a touchpad (static pressure or static capacitance), a jog wheel, and a jog switch.

As shown in FIG. 1, the A/V input unit 120 and the user input unit 130 can be merged into a single input unit 116. Various kinds of input data generated by the input unit 116 can be used to activate or deactivate memo-related functions carried out in the mobile terminal 100 according to the present invention, including a memo-writing function, memo-saving function, and memo-insertion function through the display unit 151 implemented in the form of a touchscreen. The input data can include images received through the camera 121, the user's voice received through the microphone, and touch inputs received through the display unit 151. However, the technical scope of the present invention is not limited to the description above.

The sensing unit 140 provides status measurements of various aspects of the mobile terminal 100. For example, the sensing unit 140 detects an open/closed state of the mobile terminal 100, position of the mobile terminal 100, presence of a user's contact, a touch operation of the user with respect to a particular part, orientation of the mobile terminal, and acceleration or deceleration of the mobile terminal; and generates a sensing signal for controlling operation of the mobile terminal 100. The sensing signal is delivered to the controller 180 and used by the controller 180 to perform a particular function.

The sensing unit 140 may include a touch sensor for detecting a user's touch input, a vibration sensor for detecting vibration generated based on the user's touch input, a gyro sensor for detecting rotation of the mobile terminal 100, acceleration sensor, and a geomagnetic sensor. However, the technical scope of the present invention is not limited to the aforementioned sensors.

Also, as shown in FIG. 1, the sensing unit 140 can include a pose detection sensor which includes at least one of the various types of sensors above. At this time, the pose refers to a pose of the user as well as the pose of the mobile terminal 100.

For example, in case the mobile terminal 100 is a slide-phone type, the sensing unit 140 can sense whether the slide phone is opened or closed. The sensing unit 140 can also have the function of sensing whether the power supply unit 190 supplies power or not, whether the interface unit170 is connected to an external device, and so on. Meanwhile, the sensing unit 140 can include a proximity sensor.

The output unit 150 generates output related to visual, auditory, and tactile sense and includes a display unit 151, an audio output unit 152, an alarm unit 153, and a haptic module 154.

The display unit 151 displays information processed by the mobile terminal 100. For example, when the mobile terminal 100 is in a call mode, the display unit 151 may display a user interface (UI) or a graphic user interface (GUI) associated with the call. If the mobile terminal 100 is in a video communication mode or a photograph mode, the display unit 151 may display a captured and/or received picture, a UI, or a GUI.

The display unit 151 includes at least one of a liquid crystal display (LCD), a thin film transistor liquid crystal display (TFT LCD), an organic light-emitting diode (OLED), a flexible display, or a 3-dimensional display.

The display unit 151 may be made of a transparent or light-transmission type material, through which the user can see the surroundings of the mobile terminal 100. This kind of display can be called a transparent display. A transparent LCD is a typical example of the transparent display. The rear structure of the display unit 151 can also be made of the light-transmission type material. Due to this structure, the user can see an object located behind the terminal body through the area occupied by the display unit 151 of the terminal body.

At least two or more display units 151 may be provided depending on the implementation type of the mobile terminal 100. For example, a plurality of display units 151 may be disposed on a single surface of the mobile terminal 100 spaced apart from each other or built into a single body. Alternatively, each of a plurality of display units 151 may be disposed on different surfaces of the mobile terminal 100.

If the display unit 151 and a sensor for detecting a touch action (hereinafter, it is referred to as a touch sensor) are constructed to form a mutual-layered structure (hereinafter, it is referred to as a touch screen), the display unit 151 may be used as an input device as well as an output device. The touch sensor may be constructed in the form of a touch film, a touch sheet, or a touchpad.

The touch sensor can be configured to convert a pressure applied to a specific portion of the display unit 151 or a variation of electrostatic capacity generated at a specific portion of the display unit 151 to an electric input signal. The touch sensor can be configured to detect a pressure at the time of a touch input as well as the position and the area of the touch input.

If a touch input is applied to the touch sensor, a signal(s) corresponding to the touch input is transferred to a touch controller. The touch controller processes the signal(s) and then transfers corresponding data to the controller 180. The controller 180 is then determines which portion of the display unit 151 has been touched.

A proximity sensor can be disposed in an inside area of the mobile terminal enclosed by the touch screen or around the touchscreen. The proximity sensor refers to a sensor capable of detecting presence or non-presence of an object approaching a specific detecting surface or an object located around the proximity sensor by using electromagnetic field strength or infrared rays without employing a mechanical contact. Accordingly, the proximity sensor exhibits greater durability and greater utility than a contact type sensor.

Examples of the proximity sensor include a transmissive photoelectric sensor, a direct reflective photoelectric sensor, a mirror reflective photoelectric sensor, a high frequency oscillation proximity sensor, an electrostatic capacity proximity sensor, a magnetic-type proximity sensor, and an infrared proximity sensor.

If the touch screen is an electrostatic type touch screen, the proximity sensor detects an approach of the cursor by using a variation of an electric field according to the approach of the cursor. In this case, the touch screen (touch sensor) can be classified as a proximity sensor.

The proximity sensor senses a proximity touch and a proximity touch pattern (for example, proximity touch distance, proximity touch direction, proximity touch speed, proximity touch duration, proximity touch position, and proximity touch movement state). Information corresponding to the sensed proximity touch action and proximity touch pattern can be displayed on the touch screen.

The audio output unit 152 may output audio data received from the wireless communication unit 110 in a call-receiving mode, a communication mode, a recording mode, a voice recognition mode, or a broadcast receiving mode. The audio output unit 152 may also output audio data stored in the memory 160. The audio output unit 152 outputs an audio signal related to a function (for example, a call signal receiving sound, a message receiving sound, and so on) performed by the mobile terminal 100. The audio output unit 152 includes a receiver, a speaker, or a buzzer. Also, the audio output unit 152 can output a sound through an earphone jack 116. The user can listen to an output sound by connecting an earphone to the earphone jack 116.

The alarm unit 153 outputs a signal for notifying occurrence of a particular event associated with the mobile terminal 100. Typical events include a call signal reception, a message reception, a key signal input, and a touch input. The alarm unit 153 may employ a different type of a signal rather than a video or an audio signal, for example, a signal for notifying occurrence of an event by using vibration. The video or audio signal can also be output through the display unit 151 or the audio output unit 152.

The haptic module 154 generates various tactile effects that can be sensed by the user. Vibration is a representative tactile effect generated by the haptic module 154. The haptic module 154 can control the strength and the pattern of a vibration generated. For example, different vibrations can be synthesized or can be output one after another.

The haptic module 154 can generate various haptic effects in addition to vibration. For example, the haptic module 154 can generate an effect caused by a pin array vertically moving against skin being touched, an effect caused by an air injection force via an injection hole, an effect caused by an air suction force via a suction hole, an effect caused by a stimulus input skimming on a skin surface, an effect caused by a contact with an electrode, an effect caused by electrostatic force, or an effect caused by realizing a hot or cold sense using an endothermic or exothermic device.

The haptic module 154 can be configured to provide a haptic effect via direct contact. The haptic module 154 can also be configured to enable the user to experience the haptic effect via muscular sense of a finger or an arm of the user. Two or more haptic modules 154 can be installed according to a structure of the mobile terminal 100.

The memory 160 stores programs for operation of the controller 180 and temporarily stores input/output data (for example, phonebook, message, still picture, moving picture, and the like). The memory 160 can store data about vibration and sound of various patterns output when the user touches the touch screen.

The memory 160 can include at least one type of storage media from among a flash memory, a hard disk, a multimedia card micro type memory, a card type memory (e.g., SD memory, XD memory, etc.), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk. The mobile terminal 100 can operate in association with a web storage that performs a storage function of the memory 160 on the Internet.

The interface unit 170 performs the role of a passage to all kinds of external devices connected to the mobile terminal 100. The interface unit 170 receives data or power from an external device and delivers the received data or power to individual elements within the mobile terminal 100. The interface unit 170 may be configured to transfer data from the mobile terminal 100 to an external device.

For example, the interface unit 170 may include a wired/wireless headset port, an external charger port, a wired/wireless data port, a memory card port, a port for coupling the mobile terminal 100 to a device having an identity module, an audio input/output (I/O) port, a video input/output (I/O) port, and an earphone port.

The interface unit 170 can include a card slot into which a user identification module (UIM) of the card type can be installed. Then the user identification module can be connected to the mobile terminal 100 through the card slot. At this time, a plurality of user identification modules can be connected to the interface unit 170.

The interface unit 170 can be configured to perform as a passage for supplying power to the mobile terminal 100 when the mobile terminal 100 is connected to an external cradle. Also, various command signals input through the cradle by the user can be delivered to the mobile terminal through the interface unit 170. Various command signals or power input through the cradle can be used to indicate that the mobile terminal has been correctly loaded into the cradle.

The controller 180 typically controls the overall operation of the mobile terminal 100. For example, the controller 180 performs control and processing related to voice calls, data communication, and video calls. The controller 180 may include a multimedia module 181 meant for play of multimedia contents. The multimedia module 181 can be implemented inside the controller 180 or separately from the controller 180.

The controller 180 can perform a pattern recognition process for recognizing a handwriting input or a drawing input on the touch screen as a character or an image.

The power supply unit 190 receives internal and external power by the control of the controller 180 and provides power required for operation of various components for the mobile terminal 100.

Various embodiments of the present invention described in this document can be implemented within a recording medium that can be read by a computer or a device similar thereto by using software, hardware, or a combination thereof.

As for hardware implementation, embodiments of the present invention can be implemented by using at least one of application specific integrated circuits (ASICs), digital signal processors (DSPs), digital signal processing devices (DSPDs), programmable logic devices (PLDs), field programmable gate arrays (FPGAs), processors, controllers, microcontrollers, microprocessors, and electrical units for performing functions. In some cases, the embodiments may be implemented by the controller 180.

In the case of software implementation, embodiments of the present invention related to a procedure or a function can be implemented with a separate software module which enables at least one function or operation to be carried out. Software codes may be implemented by a software application written in a suitable programming language. Also, the software codes can be stored in the memory 160 and executed by the controller 180.

So far, the structure of the mobile terminal 100 according to the present invention has been described with reference to FIG. 1. In what follows, characteristics of the mobile terminal 100 according to the present invention capable of preventing degradation of communication quality due to a user's grip on the mobile terminal will be described in more detail.

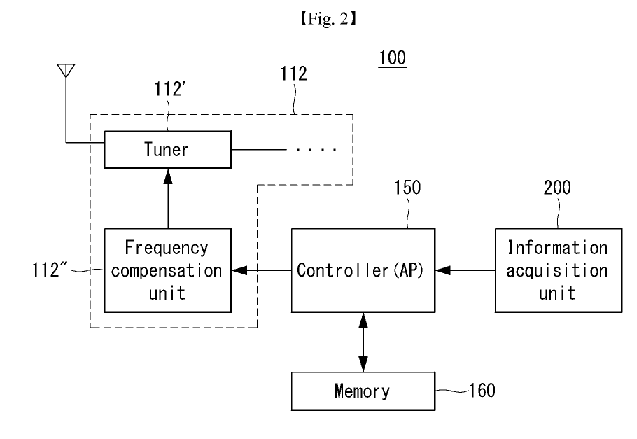

FIG. 2 is a block diagram of a mobile terminal 100 according to another embodiment of the present invention. With reference to FIG. 2, the mobile terminal 100 comprises a tuner 112′, an information acquisition unit 200, a controller 180, a memory 160, and a frequency compensation unit 112″. FIG. 2 describes only the elements required for describing a function for preventing degradation of radio sensitivity due to a user's grip on the mobile terminal 100. In what follows, operations and functions of the respective elements will be described in more detail.

The tuner 112′ forms part of the mobile communication module 112, and the impedance of the tuner 112′ matches a particular resonance frequency allocated to the mobile terminal 100 for connection to a mobile communication network. In what follows, the particular resonance frequency allocated to the mobile terminal 100 is called a target resonance frequency of the mobile terminal 100.

If the user grips the mobile terminal 100, impedance of the tuner 112′ changes, and the resonance frequency of the turner 112′ deviates from the target resonance frequency accordingly. This is referred to as impedance mismatch of the tuner 112′ due to the user's grip. Because of the impedance mismatch, communication quality through a mobile communication network may be degraded.

Information related to the impedance mismatch of the tuner 112′ refers to the information representing an impedance mismatch result due to the user's grip. The impedance mismatch information may include an impedance change value of the tuner 112′ due to the user's grip, a changed resonance frequency of the tuner 112′, and the grip position of the user. However, the technical scope of the present invention is not limited to the description above.

The information acquisition unit 200 can obtain the impedance mismatch-related information. Among the impedance mismatch-related information, the grip position of the user can be obtained by the sensing unit 140. In other words, the sensing unit 140 can sense the position (namely, impedance mismatch information) of a touch input due to the user's grip on the mobile terminal 100. The sensing unit 140 can be composed of a touch sensing module for sensing a touch position of the user's grip, a pressure sensing module, and so on. However, the technical scope of the present invention is not limited to the description above.

Meanwhile, the sensing modules can be installed at least in a part of a side surface of the mobile terminal 100 body. For example, the sensing modules can be disposed on at least one side surface of four side surfaces of the rectangular shaped mobile terminal 100 body. Also, the sensing modules can be disposed on the rear surface of the rectangular shaped mobile terminal 100. However, the technical scope of the present invention is not limited to the description above.

Also, the information acquisition unit 200 can be implemented as a sensing means for obtaining a changed impedance value itself of the turner 112′ due to the user's grip. Also, the information acquisition unit 200 can be implemented as a sensing means for obtaining a changed resonance frequency itself of the tuner 112′ due to the user's grip from among the impedance mismatch information.

Based on the impedance mismatch-related information, the controller 180 can generate a control signal intended to compensate for the difference between the resonance frequency of the tuner 112 changed due to the user's grip and the target resonance frequency. The control signal may be generated to control capacitance of the tuner 112′. At this time, the controller 180 may be an application processor (AP), which is a main processor of the mobile terminal 100.

Meanwhile, the controller 180 can generate a control signal for eliminating impedance mismatch of the tuner 112′ by using data stored in the memory 160. At this time, the memory 160 may hold data for a method for eliminating impedance mismatch according to the type of impedance mismatch-related information.

The frequency compensation unit 112″ can receive the control signal. Before the control signal is received, the impedance of the tuner 112′ mismatches the target resonance frequency due to the user's grip. The frequency compensation unit 112″, in response to the control signal, can change the impedance of the tuner 112′ to match the target resonance frequency. Then the resonance frequency of the tuner 112′ is compensated for by the impedance change to match the target resonance frequency. And this process indicates that the impedance change compensates for degradation of communication quality due to the user's grip.

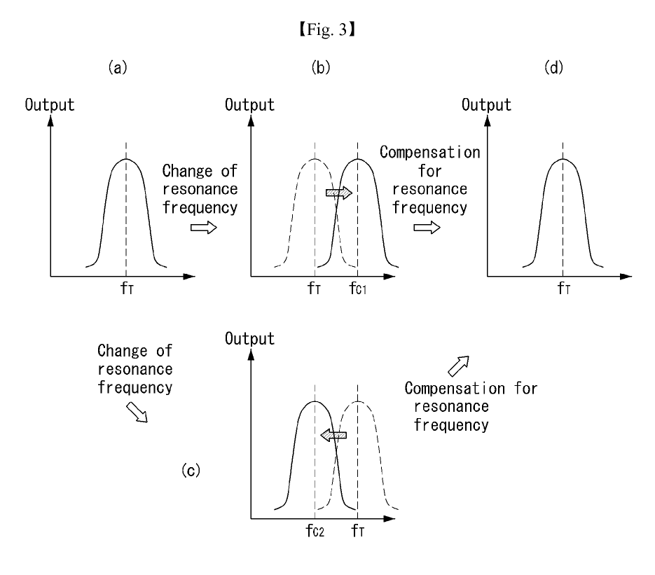

FIG. 3 illustrates a resonance frequency compensation operation of a tuner 112′ carried out in a mobile terminal 100 according to the present invention.

FIG. 3(a) illustrates a situation where the resonance frequency of the tuner 112′ is kept to the target resonance frequency f_{T} before the user grips the mobile terminal 100. While in the situation of FIG. 3(a), the user grips the mobile terminal 100. Then the resonance frequency of the turner 112′ can be made higher than the target resonance frequency f_{T} as shown in FIG. 3(b). Similarly, as shown in FIG. 3(c), the resonance frequency of the tuner 112′ can be made lower than the target resonance frequency f_{T}.

Then communication quality of the mobile terminal 100 can be degraded. Accordingly, as shown in FIG. 3(d), the mobile terminal 100 can prevent degradation of communication quality by compensating for the difference between the resonance frequency of the tuner 112′ and the target resonance frequency f_{T}.

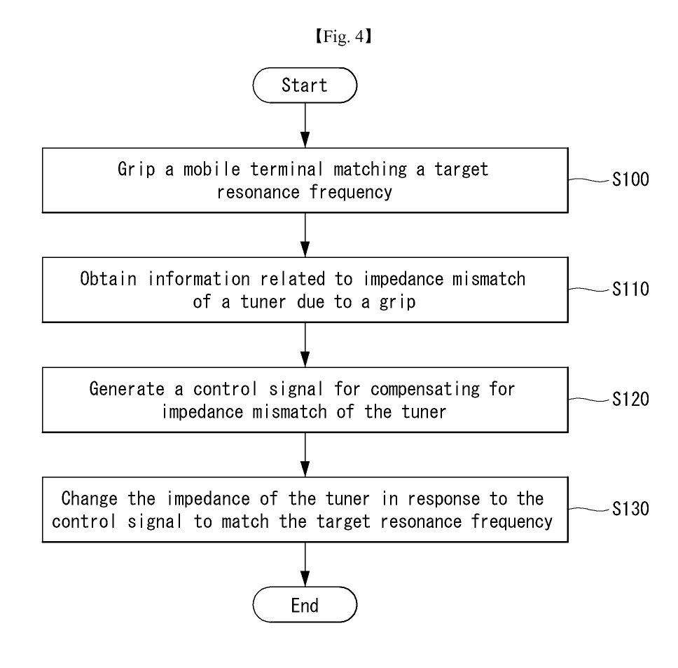

FIG. 4 illustrates one example of a method for operating a mobile terminal according to the present invention. In what follows, a method for operating the mobile terminal will be described with reference to related drawings.

The user grips the mobile terminal 100 which matches a target resonance frequency S100. Then the impedance of the tuner 112′ of the mobile terminal 100 is changed, which causes impedance mismatch of the tuner 112′.

The information acquisition unit 200 obtains impedance mismatch-related information of the tuner 112′, S110. At this time, as described above, the impedance mismatch-related information may include position of the user's grip, an impedance change value of the tuner 112′, a resonance frequency change value of the tuner 112′, and so on.

Based on the impedance mismatch-related information, the controller 180 generates a control signal for impedance compensation for the tuner 112′, S120. Then the frequency compensation unit 112″ receives the control signal and in response to the received control signal, changes the impedance of the tuner 112′ to match the target resonance frequency S130.

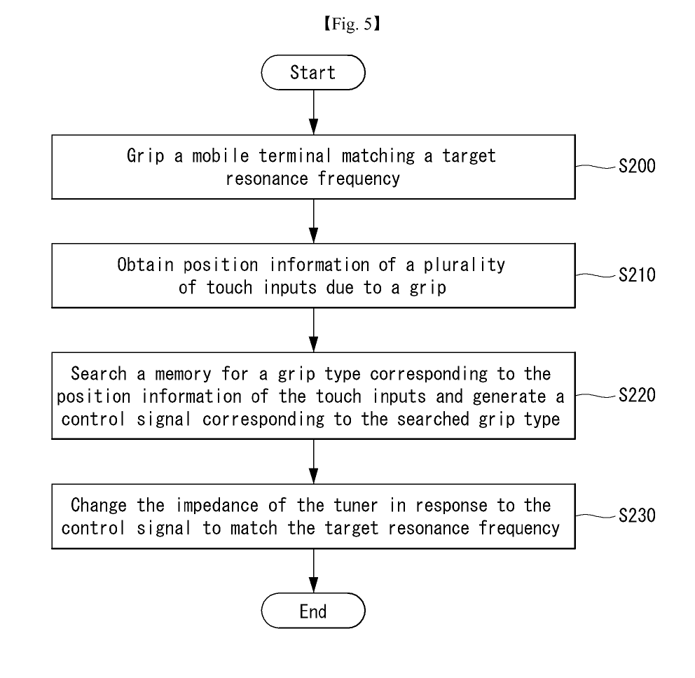

FIG. 5 illustrates another example of a method for operating a mobile terminal according to the present invention. In what follows, a method for operating the mobile terminal will be described with reference to related drawings.

The user grips the mobile terminal 100 matching a target resonance frequency S200. Then the sensing unit 140 obtains information about a plurality of touch positions due to the user's grip S210. The sensing unit 140 can be implemented by a touch sensing module or a pressure sensing module for sensing a touch position due to the user's grip, and the modules can be installed on a side surface or a rear surface of the terminal body.

The information about position of the plurality of touch positions can be the information related to impedance mismatch of the tuner 112′. This is so because resonance frequency and impedance change due to impedance mismatch of the tuner 112′ can be induced based on the information about the plurality of touch positions.

Then the controller 180 searches the memory 160 for a grip type corresponding to the touch position and generates a control signal corresponding to the searched grip type S220. More specifically, the memory 160 stores data corresponding to a method for compensating for a resonance frequency of the tuner 112′ according to a grip type. The controller 180 searches for data corresponding to a grip type based on a touch position and generates a control signal based on the searched data.

The frequency compensation unit 112″ changes the impedance of the tuner 112″ to match the target resonance frequency in response to the control signal S230.

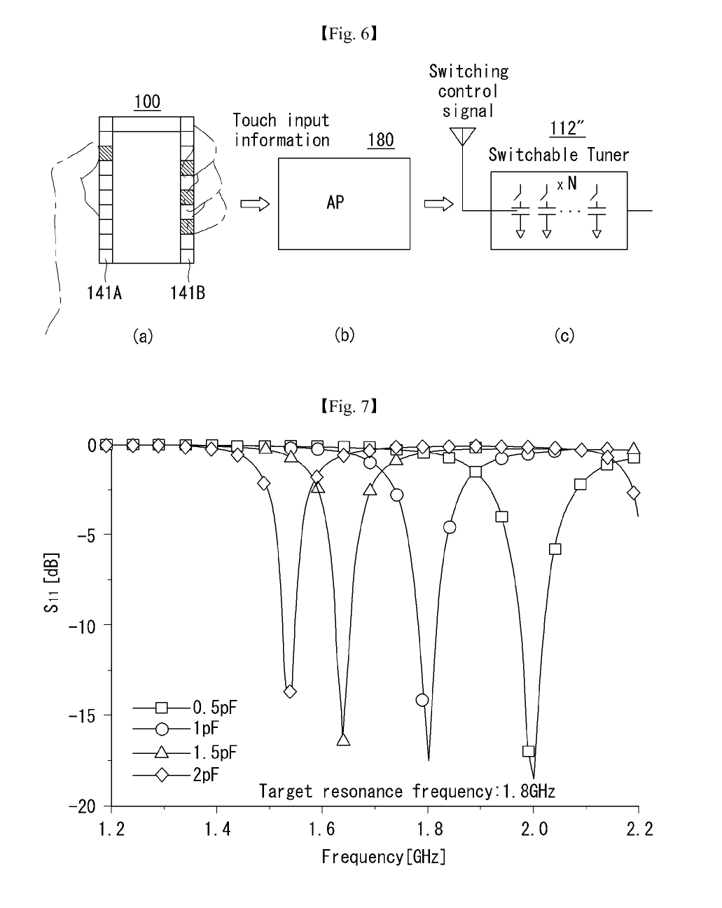

FIG. 6 illustrates an example where resonance frequency compensation for a tuner 112′ is carried out according to a method for operating a mobile terminal of FIG. 5.

With reference to FIG. 6(a), the mobile terminal 100 obtains a plurality of touch positions due to the user's grip through the sensing module 141A, 141B installed on vertical surfaces of the terminal body and transmits the obtained touch positions to the AP 180.

Then the AP 180 receives the touch positions and based on the received touch positions, generates a switching control signal for controlling switching operation of a plurality of switches controlling connection of a plurality of capacitors included in the frequency compensation unit 112″ to the tuner 112′. The AP 180 transmits the switching control signal to the frequency compensation unit 112″.

The frequency compensation unit 112″, in response to the switching control signal, controls the switching operation of the plurality of switches and changes impedance of the tuner 112″. As a result of frequency change, the resonance frequency of the tuner 112′ is compensated for to match the target resonance frequency. Therefore, degradation of communication quality due to the user's grip can be prevented.

FIG. 7 is a graph illustrating a method for compensating for resonance frequency of a tuner 112′ of a mobile terminal 100 according to a method for operating a mobile terminal of FIG. 6.

The target resonance frequency of the tuner 112′ is 1.8 GHz. At this time, capacitance of the tuner is 1 pF. If the capacitance of the tuner 112′ changes to 0.5 pF due to the user's grip on the mobile terminal 100, the resonance frequency of the tuner 112′ is changed to 2.0 GHz. Then the mobile terminal 100 increases the capacitance of the tuner 112′ to 1 pF, thereby lowering the resonance frequency of the tuner 112′ again to 1.8 GHz and compensating for the change of resonance frequency of the tuner 112′ due to the user's grip.

If the capacitance of the tuner 112′ is increased to 1.5 pF or 2 pF due to the user's grip, the resonance frequency of the tuner 112′ is decreased to 1.8 GHz. In this case, the mobile terminal 100 reduces the capacitance of the tuner 112′ to 1 pF, thereby increasing the resonance frequency of the tuner 112′ again to 1.8 GHz and compensating for the change of resonance frequency of the tuner 112′ due to the user's grip.

FIGS. 6 and 7 describe a situation where impedance mismatch of the tuner 112′ is compensated for by changing the number of capacitors connected to the tuner 112′ adaptively; however, the technical scope of the present invention is not limited to the description above. For example, the mobile terminal 100 according to the present invention can compensate for impedance mismatch of the tuner 112′ by controlling inductance of the tuner 112′.

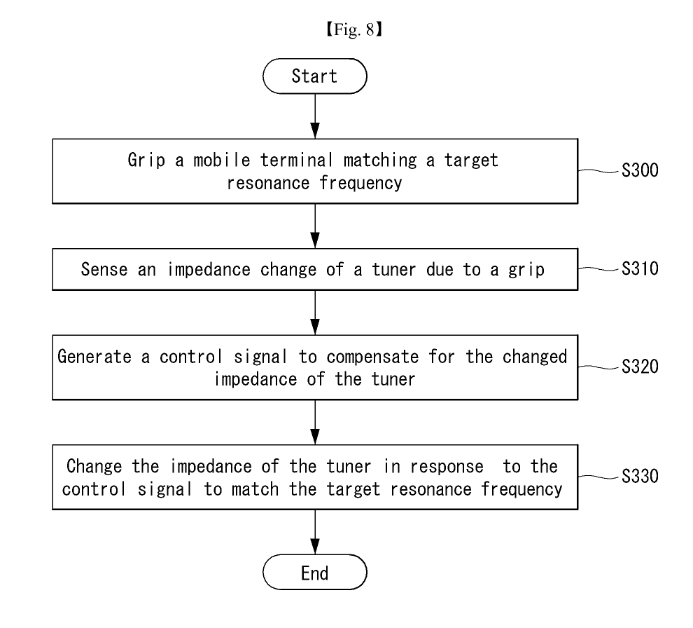

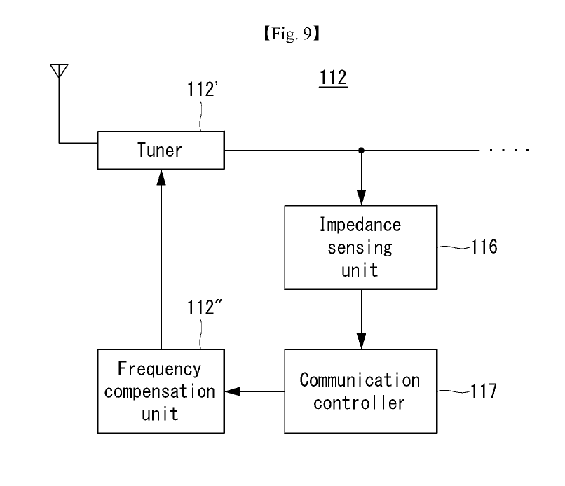

FIG. 8 is a flow diagram illustrating a yet another example of a method for operating a mobile terminal according to the present invention. FIG. 9 is a block diagram of a mobile communication module 112 of a mobile terminal 100 according to the present invention, intended for carrying out a method for operating a mobile terminal of FIG. 8. In what follows, the method for operating a mobile terminal will be described with reference to related drawings.

The user grips the mobile terminal 100 matching a target resonance frequency S300. The impedance of the tuner 112′ is changed due to the user's grip on the mobile terminal 100. In other words, impedance mismatch of the tuner 112′ is caused by the user's grip.

Then the impedance sensing unit 116 obtains impedance change information of the tuner 112′ and delivers the information to the communication controller 117, S310. Then the communication controller 117 generates a control signal to compensate for the changed impedance of the tuner 112′ based on the impedance change information and delivers the control signal to the frequency compensation unit 112″ S320.

Then the frequency compensation unit 112″, based on the control signal, changes the impedance of the tuner 112′ to match a target resonance frequency S330. As described earlier, the impedance matching operation can be carried out by changing capacitance or inductance of the tuner 112′.

As described earlier, the impedance matching operation (namely, resonance frequency compensation operation) of the tuner 112′ according to a method for operating a mobile terminal described with reference to FIGS. 8 and 9 can be carried out within the mobile communication module 112. This is a feature differentiating the current method from the one described with reference to FIGS. 2 to 7 where the control signal meant for impedance matching of the tuner 112′ is carried out by the controller 180.

Meanwhile, in the embodiment described with reference to FIGS. 8 and 9, impedance mismatch-related information of the tuner 112′ corresponds to the impedance change value itself of the tuner 112′. However, the technical scope of the present invention is not limited to the description above.

For example, as described above, the impedance mismatch information of the tuner 112′ may be the information indicating change of the resonance frequency of the tuner 112′. At this time, the mobile communication module 112 should include an element for sensing the resonance frequency change of the tuner 112′ rather than the impedance sensing unit 116. The impedance sensing unit or a structure for sensing resonance frequency change of the tuner 112′ may correspond to the information acquisition unit 200 of FIG. 2.

Though not shown in the figure, the mobile communication module 112 of the mobile terminal 100 according to the present invention can receive the touch position of the mobile terminal 100 according to the user's grip sensed by the sensing unit 140 and directly carry out impedance matching with respect to a target resonance frequency of the tuner 112′ by using the received touch position. At this time, as described above, the mobile communication module 112 can reference the data stored in the memory 160.

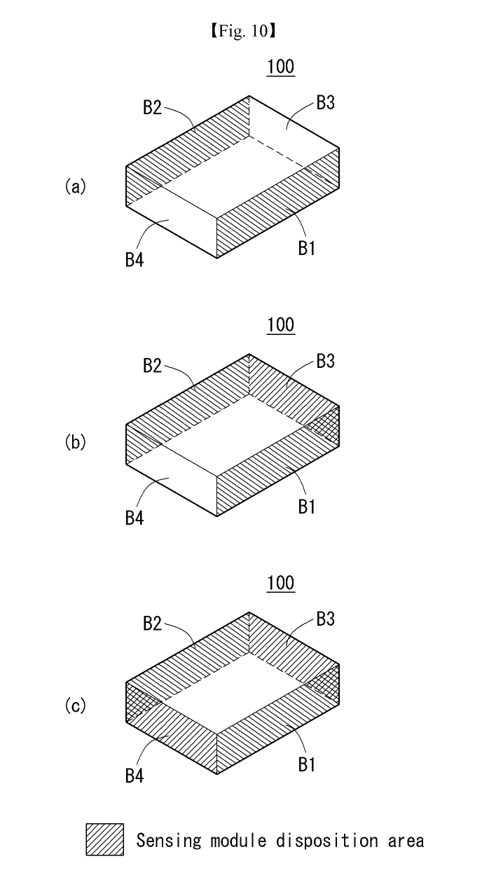

FIG. 10 illustrates examples where a sensing module for sensing a touch position due to a user's grip on a mobile terminal 100 is disposed therein according to the present invention.

With reference to FIG. 10(a), the sensing module can be installed on side surfaces (B1 and B2) of the mobile terminal 100 body in a vertical direction. With reference to FIG. 10(b), the sensing module can be installed on side surfaces (B1 and B2) of the mobile terminal 100 body in a vertical direction and on a upper side surface B3 of the body. Referring to FIG. 10(c), the sensing module can be installed on side surfaces (B1 and B2) of the mobile terminal 100 body in a vertical direction and on a upper and a lower surface (B3 and B4) of the terminal body. However, the mobile terminal 100 according to the present invention is not limited to the aforementioned disposition examples of the sensing module.

Meanwhile, the sensing module can be installed in the mobile terminal 100 according to the present invention at a position where an antenna is installed or at a position adjacent to the antenna. This is so because there is a high chance that the antenna exerts a large influence on the impedance mismatch due to a user's grip.

The method for operating a mobile terminal according to the present invention can individually recorded in a computer-readable medium after being implemented in the form of a program that can be executed through various computer means. The computer-readable medium can include program commands, data file, or data structures individually or in the form of a combination thereof. The program may require a recording medium specially designed or composed for the present invention, or it may use such a kind of a recording medium well known to those skilled in the computer software technology.

Examples of a computer-readable recording medium include a magnetic media such as a hard disk, a floppy disk, and a magnetic tape; an optical media such as CD-ROM and DVD; a magneto-optical media such as a floptical disk; a hardware device specially composed to store and carry out program commands, such as ROM, RAM, and flash memory. Examples of a program include not only machine codes generated by a compiler but also high-level language codes that can be executed by a computer using an interpreter. The hardware device can be constructed so that it can be operated as one or more software modules or vice versa.

Though the present invention has been described with reference to a limited number of embodiments and drawings, the present invention is not limited to the embodiments, and it should be understood that various modifications and changes can be implemented from the descriptions by those skilled in the art.

Therefore, the technical scope of the present invention should not be limited to the embodiments of this document, but it should be defined by the appended claims or equivalents of the appended claims.

### INDUSTRIAL APPLICABILITY

A mobile terminal according to the present invention can be used widely by the users who want communicate with others with the best communication quality. A mobile communication module according to the present invention can be used by mobile terminal manufacturers who want to produce mobile terminals of excellent communication quality.

1. A mobile terminal, comprising:
a mobile communication module including a tuner matching a predetermined target resonance frequency for mobile communication;
an information acquisition unit obtaining information related to impedance mismatch of the tuner, which is caused by a user's grip on the mobile terminal and changes resonance frequency of the tuner;
a controller generating an impedance control signal for compensating for the resonance frequency of the tuner from the changed resonance frequency to the target resonance frequency based on the information related to impedance mismatch of the tuner; and
a frequency compensation unit changing the impedance of the tuner mismatched by the user's grip on the mobile terminal so that the impedance of the tuner can match the target resonance frequency in response to the impedance control signal.

2. The mobile terminal of claim 1, wherein the information acquisition unit includes a touch position sensing module disposed on a side surface of the mobile terminal body, and the information related to impedance mismatch of the tuner includes position information of a plurality of touch inputs due to the user's grip on the mobile terminal, which is sensed by the touch position sensing module.

3. The mobile terminal of claim 2, wherein the mobile terminal further comprises a memory storing information related to impedance mismatch of the tuner according to a grip type of the user, and if the grip type of the user is sensed by the touch position sensing module, the controller searches the memory to generate an impedance control signal due to the sensed grip type.

4. The mobile terminal of claim 1, wherein the impedance mismatch-related information of the tuner includes impedance change information of the tuner due to the user's grip.

5. The mobile terminal of claim 1, wherein the impedance mismatch-related information of the tuner includes resonance frequency change information of the tuner due to the user's grip.

6. The mobile terminal of claim 2, wherein the frequency compensation unit controls capacitance of the tuner in response to the impedance control signal so that the impedance of the tuner can be changed to match the target resonance frequency.

7. The mobile terminal of claim 4, wherein the frequency compensation unit comprises a plurality of capacitors; and
a plurality of switches connecting one of the plurality of capacitors to the tuner in response to the impedance control signal.

8. A mobile communication module, comprising:
a mobile communication module including a tuner matching a predetermined target resonance frequency for mobile communication;
an information acquisition unit obtaining information related to impedance mismatch of the tuner, which is caused by a user's grip on the mobile terminal and changes resonance frequency of the tuner;
a communication controller generating an impedance control signal for compensating for the resonance frequency of the tuner from the changed resonance, frequency to the target resonance frequency based on the information related to impedance mismatch of the tuner; and
a frequency compensation unit changing the impedance of the tuner mismatched by the user's grip on the mobile terminal so that the impedance of the tuner can match the target resonance frequency in response to the impedance control signal.

9. The mobile communication module of claim 8, wherein the information related to impedance mismatch of the tuner includes information of impedance change of the tuner caused by the user's grip on the mobile terminal.

10. The mobile communication module of claim 8, wherein the information related to impedance mismatch of the tuner includes information of resonance frequency change of the turner caused by the user's grip on the mobile terminal.

11. The mobile communication module of claim 8, wherein the information related to impedance mismatch of the tuner includes position information of a plurality of touch inputs due to the user's grip sensed by a touch input sensing module installed on a side surface of the mobile terminal body.

12. The mobile communication module of claim 11, wherein the mobile communication module is linked to a memory storing information related to impedance mismatch of the tuner according to a grip type of the user, and
the communication controller searches the memory if a grip type of the user is received from the touch position sensing module and generates an impedance control signal according to the sensed grip type.

13. The mobile communication module of claim 9, wherein the frequency compensation unit changes the impedance of the tuner to match the target resonance frequency of the tuner by controlling capacitance of the tuner in response to the impedance control signal.

14. A mobile communication terminal including a mobile communication module of claim 9.
